(19) United States
(12) Patent Application Publication
(10) Pub. No.: US 2026/0331006 A1
(43) Pub. Date: Oct. 22, 2026

(54) DIGITAL DISPLAY ASSEMBLY WITH INTEGRATED MEMBRANE SWITCH

(71) Applicant: Almax Manufacturing, Kirkland, WA (US)

(72) Inventor: Max Christian Burk, Phoenix, AZ (US)

(21) Appl. No.: 19/183,016

(22) Filed: Apr. 18, 2025

(51) Int. Cl. G09F 9/302; G06F 3/01; H01L 25/075

(52) U.S. Cl. CPC G09F 9/3023; G06F 3/016; H10W 90/00

(57) ABSTRACT

A digital display assembly may comprise an overlay layer configured to convey alphanumeric information and receive user input. The overlay layer may include an array of openings configured to receive a digital display and a raised area configured to provide tactile feedback via a tactile membrane switch. The digital display assembly may further comprise a first printed circuit board disposed beneath the overlay layer, on which the tactile membrane switch is formed. The first printed circuit board may comprise a microcontroller disposed on the first printed circuit board. The digital display assembly may further comprise a second printed circuit board disposed beneath the overlay layer, on which the digital display is disposed. The digital display assembly may further comprise a back adhesive layer disposed beneath the first printed circuit board and the second printed circuit board.

### BACKGROUND

Digital displays are ubiquitous in modern electronics, and are useful to present information in a visual form in various devices such as kitchen appliances, digital clocks, and the like. Often, these devices and other commonly used electronics convey alphanumeric characters via seven segment displays or dot matrix displays. Thus, seven segment displays and dot matrix displays are themselves ubiquitous in modern electronics.

A seven segment display is an arrangement of light generating or light controlling components (typically light emitting diodes also known as LEDs) into a generally rectangular pattern. A single seven segment display can be made to represent the numerical digits 0 to 9 and most letters of the Latin alphabet by selectively lighting individual LEDs of the seven segment display. Dot matrix displays display visual information using a two-dimensional grid of light-emitting elements, each light-emitting element being referred to as a “pixel” or “dot.” The presence or absence of light from each pixel forms characters or graphics. Accordingly, seven segment displays are well suited for any electronic device where it is necessary to display alphanumerical information.

Various applications in which digital displays, such as seven segment displays and dot matrix displays, are incorporated require a user interface to control the alphanumeric information shown on the digital display. In most cases, a keypad is the means by which a user interfaces with a digital display. A keypad is an electronic input device having an arrangement of digits, symbols, or letters corresponding to what can be shown on a digital display. Conventionally, a keypad is a separate component that must be electronically connected to a digital display in order to be useful. Therefore, conventional applications of digital displays require a keypad module to be interfaced with the digital display.

However, conventional methods interfacing keypads with digital displays face several limitations. One such limitation is that the physical integration of separate display and keypad components is cumbersome, often requiring multiple controllers and integrated circuits (ICs). As a result, the final assembly of conventional display and keypad components is usually bulky and not well suited for applications where a thinner display profile is preferred and/or required. Moreover, the separate purchase and fabrication of components carries considerable cost impact. In such cases, conventional display and keypad assemblies are also limited to monochromatic display of information, which is not well suited for applications where it is necessary to convey color information as well as alphanumeric information.

Accordingly, there is a need for technologies that overcome the aforementioned deficiencies found in conventional approaches to manufacturing seven segment and/or dot matrix displays and interfacing the same with keypad modules.

### BRIEF DESCRIPTION OF THE DRAWINGS

The Detailed Description is set forth with reference to the accompanying figures. In the figures, the left-most digit(s) of a reference number identifies the figure in which the reference number first appears. The use of the same reference numbers in different figures indicates similar or identical items. Furthermore, the drawings may be considered as providing an approximate depiction of the relative sizes of the individual components within individual figures. However, the drawings are not to scale, and the relative sizes of the individual components, both within individual figures and between the different figures, may vary from what is depicted. In particular, some of the figures may depict components as a certain size or shape, while other figures may depict the same components on a larger scale or differently shaped for the sake of clarity.

FIG. 1 is a plan view of a conventional digital display and keypad assembly, showing a seven segment display interfaced with a separate keypad module and a separate controller.

FIG. 2 is a plan view of an exemplary embodiment of a digital display assembly with integrated membrane switch in accordance with the present approach.

FIG. 3A is a cross-section view of the exemplary embodiment of FIG. 2, wherein a digital display device casing comprises various component layers in accordance with the present approach.

FIGS. 3B-3E are various plan views of the exemplary embodiment of FIGS. 2 and 3A, and further illustrating various component layers of a digital display device casing in accordance with the present approach.

FIGS. 4A-4C are various plan views of an exemplary embodiment of printed circuit board comprising a substrate of a membrane switch of a digital display device in accordance with the present approach.

FIGS. 5A-5C are various plan views of an exemplary embodiment of a printed circuit board comprising a substrate of an LED array of a digital display device in accordance with the present approach.

FIG. 6 is a plan view of an exemplary protective sheet, wherein the protective sheet includes graphics indicating the location of a membrane switch in accordance with the present approach.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the present disclosure covers all modifications, equivalents, and alternatives falling within the scope of the appended claims.

### DETAILED DESCRIPTION

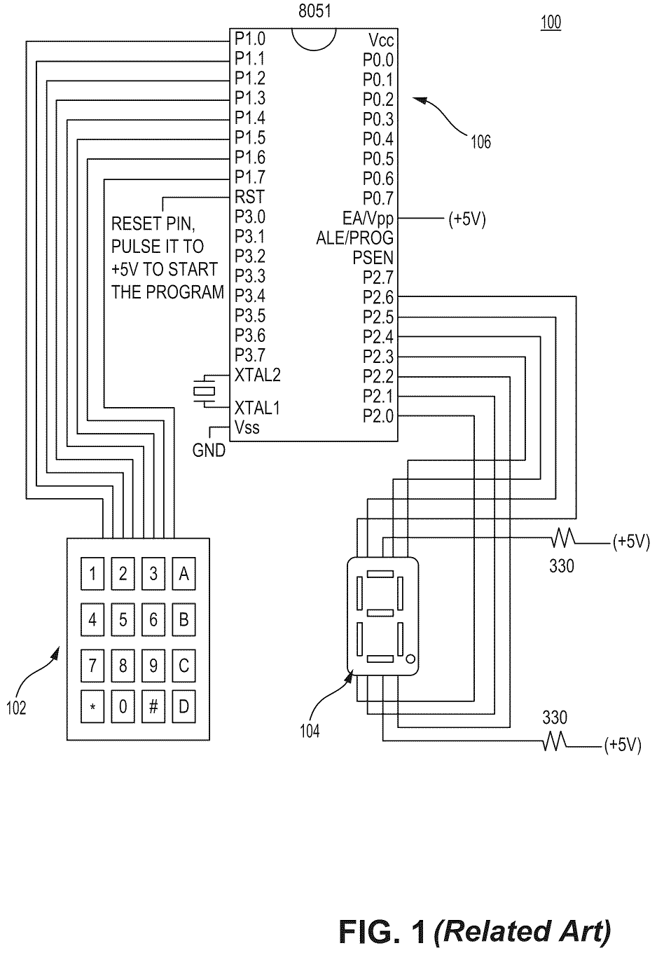

FIG. 1 is a plan view of a conventional digital display and keypad assembly 100, showing an eight segment display 104 interfaced with a separate keypad module 102 and a separate controller 106. Generally, the controller 106 serves to interpret input data that the controller 106 receives. Accordingly, the conventional keypad module 102 acts as a primary input device for the controller 106. Generally, the controller 106 is configured to temporarily store received information in data memory of the controller 106 and subsequently access and apply such received information. In the conventional digital display and keypad assembly shown, the controller 106 thus serves to use information received from the keypad module 102 to control the alphanumeric data shown on the eight segment display 104.

The illustrated keypad module 102 is a conventional 4×4 matrix keypad, such as commonly used in electronics such as microwave ovens, gas pumps, calculators and the like. As the name suggests, the illustrated keypad module 102 comprises an array of sixteen buttons arranged in four columns and four rows. However, other sizes and configurations of conventional matrix keypads (e.g., 3×4 and 4×3) are also common. One example of a conventional 3×4 matrix keypad has the numerals 1-9 disposed in sequence in the first three rows of three buttons, while the numeral 0 and pound and asterisk symbols comprise the fourth row of three buttons. In any case, conventional matrix keypads comprise a number of switches connected to one another in rows and columns. Each button of the conventional matrix keypad thus corresponds to a switch, and pressing a button simultaneously closes the switch on several circuits.

Typically, the illustrated controller 106 scans the conventional keypad module 102 to determine the state of each of the sixteen buttons as “pressed” or “not pressed.” For example, the controller 106 may apply a voltage to one row of switches at a time and then check each column for this applied voltage. Accordingly, a button is registered by the controller as being “pressed” based on which circuit indicates the applied voltage. When a button is registered by the controller as “pressed,” the eight segment display 104 displays the corresponding digit or letter. To display a particular digit or letter, the controller 106 causes a combination of LEDs of the eight segment display 104 to be illuminated. Because the eight segment display 104 can display only a single digit or letter at a time, conventional digital display devices require multiple eight and/or seven segment displays to simultaneously display multiple digits or letters. However, as illustrated, conventional eight segment displays require at least nine external connections. Thus, conventional digital display and keypad assemblies often require significant space and cost accommodations for each of the separate components including multiple controllers, support ICs and interconnects, and the like. In turn, physical integration of the separate components is cumbersome, often requiring secondary printed circuit boards, resulting in bulky final assemblies poorly suited for various applications.

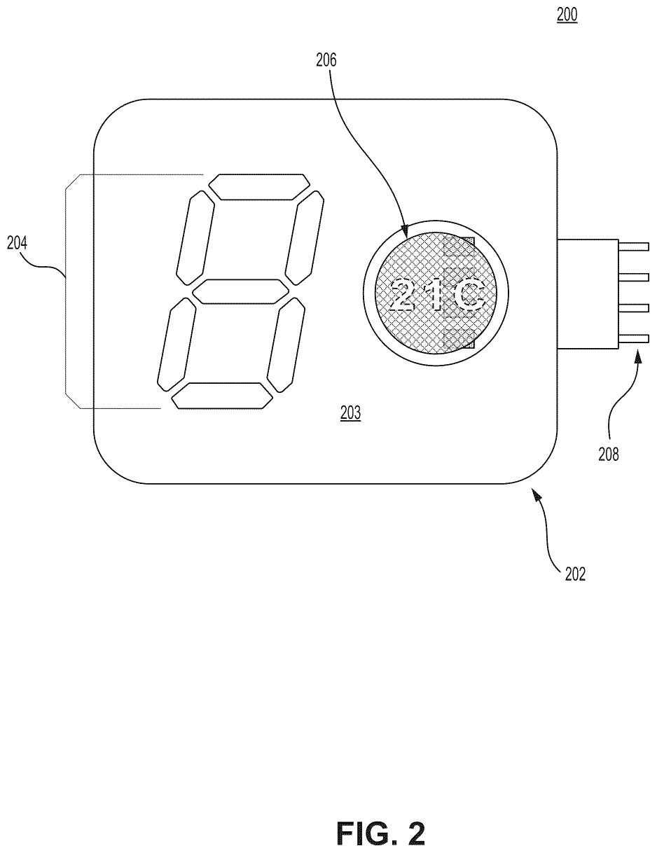

FIG. 2 is a plan view of an exemplary embodiment of a digital display assembly 200 with an integrated membrane switch in accordance with the present approach. The exemplary embodiment shown in FIG. 2 may include an assembly casing 202 formed of a non-conductive material. For example, assembly casing 202 (or one or more constituent layers thereof) can be fabricated from glass fiber-reinforced epoxy resin (Fiberglass™), from paper-reinforced phenolic resin, from polyethylene terephthalate (PET), or some other type of thermoplastic polymer resin. In some examples, the assembly casing 202 may comprise composite layers (e.g., alternating layers) of adhesive and one or more thin film polymers such as polycarbonate, (ABS), PET, or the like.

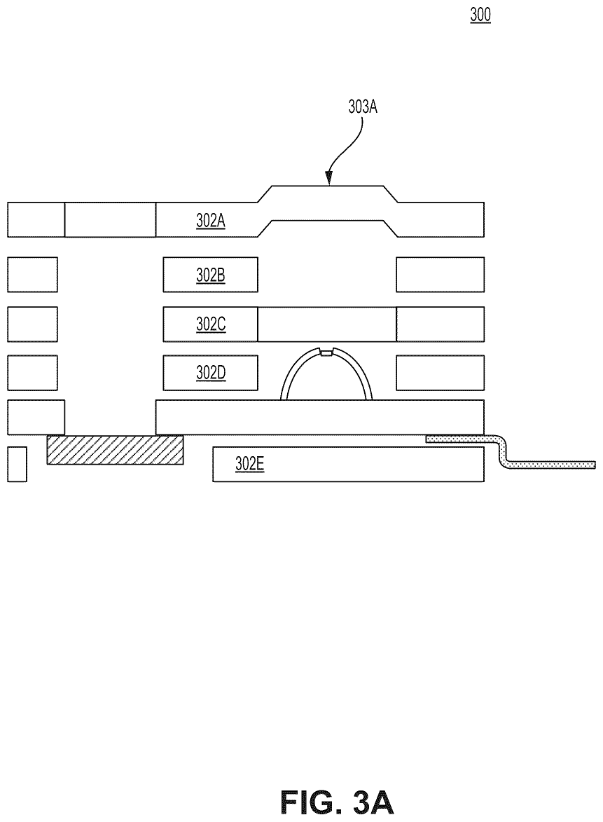

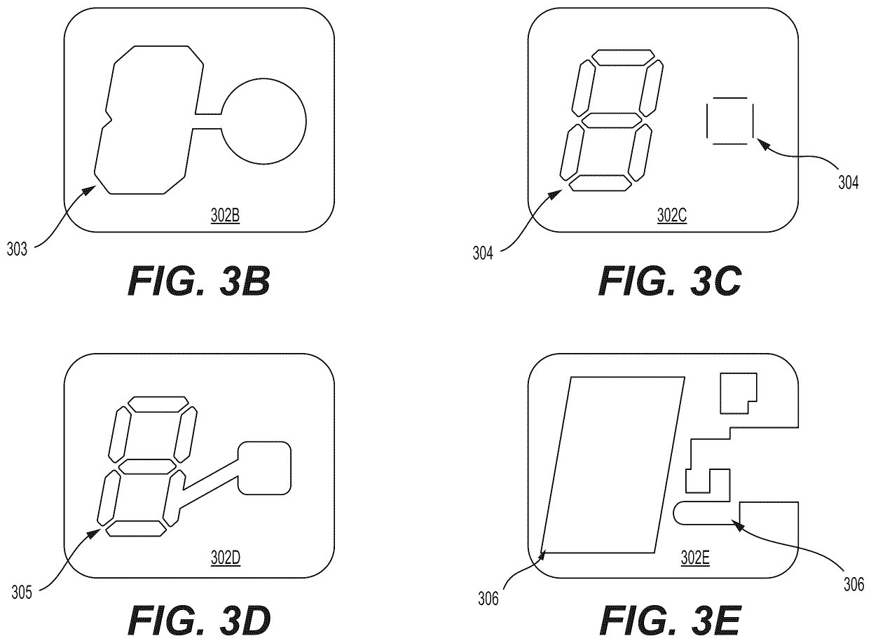

Generally, the assembly casing 202 forms a housing suitable to contain and protect the various components of the digital display assembly 200 and to enable the digital display assembly 200 to electronically couple with one or more other devices. For example, and as shown and described further below with reference to FIGS. 3A-3E, the assembly casing 202 may comprise multiple constituent layers that, when arranged together, provide the above mentioned housing for the electronic components of digital display assembly 200. Particularly, the assembly casing 202 may at least include a substantially planar display surface 203 by which the digital display assembly 200 conveys information.

In the illustrated example, the display surface 203 accommodates an LED array 204 for conveying digital information and a membrane switch 206 by which to input information. Accordingly, the surface area of the display surface 203 may be commensurate with the size of the LED array 204 and/or the membrane switch 206. Thus, an exemplary digital display assembly 200 may be manufactured having a display surface 203 of any appropriate size and surface area to accommodate any suitable number of LED arrays and/or membrane switches. Accordingly, while an individual LED array 204 and an individual membrane switch 206 are illustrated, it is contemplated that the digital display assembly 200 may include two or more LED arrays or two or more membrane switches. And, while the illustrated example shows the LED array 204 disposed near to the leftmost edge of the display surface 203 and the membrane switch disposed near to the rightmost edge thereof, other arrangements are contemplated. In the example shown, the LED array 204 comprises a seven-segment display. Though, some embodiments may comprise one or more eight-segment displays for displaying non-integer (i.e., decimal) numbers. Further still, the LED array 204 of various embodiments may comprise any of a nine segment display, a twelve segment display, a fourteen segment display, or a sixteen segment display as appropriate.

The membrane switch 206 of the illustrated example is an embossed circular button (embossing illustrated by pattern) for facilitating both aesthetic and sensory differentiation of the membrane switch 206 from the remainder of the display surface 203. However, the membrane switch 206 of various applications may take a different shape, size, orientation, or embossing style as appropriate, including pillow embossing, cosmetic rim embossing, tactile embossed graphics, or the like or may have no embossing. The membrane switch 206 may be actuated, such as by being pressed by a user's digit, to program or otherwise control the information displayed by the LED array 204. Actuation of the membrane switch 206 occurs in response to application of a force in a direction generally perpendicular to the surface area of the membrane switch 206. That is, such application of force serves to initiate resistive or capacitive contact whereby a circuit is completed.

Generally, actuation of the membrane switch 206 (or another similarly actuated button/switch as described herein) can be used to achieve functionality of the LED array 204 including turning the LED array 204 on/off, causing the LED array 204 to increment/decrement (such as when numeric information is displayed) thereon. Thus, the membrane switch 206 of examples may be in electronic communication with a microcontroller (and, hence a digital display including, but not limited to the seven segment display of illustrated LED array 204). Further, it will be appreciated by those of skill in the art that a parameter associated with the tactile input received when force is applied to activate the membrane switch 206 may be utilized to communicate one more control signals to achieve other functionality.

For example, a frequency of activation of the membrane switch 206 (i.e., a number of times a user successively activates or “presses” and “releases” the membrane switch) may be communicated to a microcontroller. The microcontroller can be configured to respond to the successive activation of the membrane switch 206, for example, by causing the seven segment display to display a first visual mode or first visual information. In such a case, a first visual mode may include a first pre-programmed visual display (e.g., pre-programmed data stored in a memory accessible to the microcontroller.) In one illustrative but non-limiting example, the first visual mode corresponds to a first function (e.g., a timer, a clock, or a stop watch). Alternatively, by applying a prolonged force (such as for a threshold period of time), the membrane switch 206 may be utilized to communicate a different control signal. In this case, the microcontroller can be configured to respond to the prolonged activation of the membrane switch 206, for example, by causing the seven segment display to display a second visual mode or second visual information.

The second visual mode/visual information may generally be different than the first visual mode/visual information. For example, the second visual mode may correspond to a second function different from the first function and therefore include different pre-programmed data stored in a memory accessible to the microcontroller. In one illustrative but non-limiting example, when a first visual mode is a timer function, then a second visual mode may be a stop watch or clock. Alternatively, the second visual mode may provide the same function as the first visual mode, but dedicate separate memory thereto. In such a case, for example, the first visual mode may function as a timer to indicate lapsing of a first time frame while the second visual mode may function as a timer to indicate lapsing of a second, independent time frame. Even still, in some cases, actuation of the membrane switch 206 may initiate transition between first graphic information displayed by the LED array 204 (e.g., a first configuration of individual illuminated LEDs or pixels) and second graphic information displayed by the LED array 204 (e.g., a second, different configuration of individual illuminated LEDs or pixels). It will be appreciated that in some examples a device controller IC and an IC associated with the LED array 204 (e.g., a seven segment display or dot matrix display) are a same component with embedded firmware.

With brief reference now to FIG. 3A, illustrated therein is a cross-section view of an exemplary assembly casing 300 including a display surface (not shown) which may be similar to the display surface 203 of FIG. 2. Particularly, the assembly casing 300 includes a membrane switch that is configured as a pillow embossed key (similarly to the membrane switch described above with reference to FIG. 2.). Thus, the display surface of the illustrated example includes a raised area 303A by which a user may easily locate and actuate the membrane switch.

Returning now to FIG. 2, illustrated therein are terminals 208. The terminals 208 are connected at one end to electrically conductive traces (not shown) of a first printed circuit board (PCB) to which the membrane switch 206 is wired. Terminals 208 are configured to be coupled at the other end with a terminal plug (also not shown) and thus create an electrical connection between the membrane switch 206 and the other components of the digital display assembly 200. Generally, the terminals 208 serve to isolate, protect, and ground the electrical components comprising the digital display assembly 200.

Returning now to FIG. 3A, the assembly casing 300 of the illustrated example further includes multiple layers, including an overlay layer 302A, overlay spacer layer 302B, dome retainer layer 302C, circuit spacer layer 302D, and back adhesive layer 302E. The overlay layer 302A may comprise the display surface described above. The overlay layer 302A may generally be formed from a hardcoated polyester film, such as PET. The material selected for the overlay layer 302A (and therefore the display surface 303) is ideally embossable, texturable, and ink-receptive. For example, the overlay layer 302A may generally provide a graphic overlay surface on which visual information may be printed. For example, the display surface (i.e., overlay layer 302A) can include graphics that indicate the location where the force should be applied to activate the membrane switch(es), as well as alphanumeric text and/or symbols to indicate the function implemented when membrane switch is actuated. The overlay layer 302A may be suitable to receive solvent based screen printing inks and/or may receive combinations of both screen printing and digitally printed UV-based inks. The overlay layer 302A of examples may be of any suitable thickness (or gauge), including being between 130 microns and 250 microns. In at least one example, the overlay layer 302A may be 180 micron gauge or approximately thereto. Further, the overlay layer 302A of examples may exhibit any suitable reflective properties including being highly reflective (e.g., having a “gloss” finish) or being less reflective (e.g., having an “anti-glare” finish).

The overlay spacer layer 302B may generally serve to maintain a break between the switch contacts of the membrane switch (not shown). Therefore, the illustrated overlay spacer layer 302B is ideally formed of an insulating material such as silicone rubber. Further, the overlay spacer layer 302B may serve to adhere the overlay layer 302A to the dome retainer layer 302C, and therefore comprises a suitable adhesive on the top and bottom surfaces of the overlay spacer layer 302B. For instance, such an adhesive may be a single-sided or double-sided tape of any suitable thickness having strong bonding characteristics to low surface energy materials. In an example, the overlay spacer layer 302B is formed from a silicon rubber having a thickness of approximately 0.125 mm. As shown with brief reference to FIG. 3B, the overlay spacer layer 302B of various examples may be formed having openings 303 shaped to accommodate a segment display and a dome of a membrane switch formed therein.

The membrane switch 206 described above may be configured as a tactile switch comprising a dome structure, whereby application of force (e.g., by a user's digit pressing the dome) serves to activate the switch. Thus, the dome retainer layer 302C may serve primarily to hold in place the dome structure (illustrated in broken lines) of a membrane switch. While the illustrated dome structure is configured as a round dome, the membrane switch of various embodiments may include dome structure(s) of any suitable size and/or shape, including four-legged, triangle, oblong, etc. With brief reference to FIG. 3C, illustrated therein is a plan view of a dome retainer layer 302C of various examples having openings 304 shaped to accommodate a segment display and a dome structure of the membrane switch formed therein. Returning now to the example of FIG. 3A, the dome retainer layer 302C directly contacts the overlay spacer layer 302B from below and the circuit spacer layer 302D from above, thereby securing the dome structure in its place. In one embodiment, the dome structure is formed from a conductive metal such as stainless steel or a copper alloy, so that when the membrane switch is pressed, the metallic dome structure flattens against a circuit to create a conductive path. Alternatively, the dome structure may be formed from a plastic, in which case, conductive ink printed on a reverse side of the plastic dome structure may serve to create the conductive path when the plastic dome structure is flattened. Ideally, the dome retainer layer 302C is formed from a thin, flexible polyester film that is conducive for supporting and aligning the underlying dome structure of the membrane switch while withstanding the compressive forces to which it will be subjected. In some examples, the dome retainer layer 302C may be formed from a thin polyester material such as T60 though other suitable materials (e.g., PET materials) are contemplated herein. In this example, the dome retainer layer is formed having a thickness of approximately 0.075 mm, although the thickness may be less than or greater than 0.075 mm.

The circuit spacer layer 302D generally serves to maintain a break in the membrane switch circuit. Accordingly, the illustrated circuit spacer layer 302D is shown overlying the first PCB (which may be similar to one of the PCBs discussed in greater detail below). The circuit spacer layer 302D is thus ideally formed from an adhesive material having high temperature performance and shear strength, therefore being suited for bonding to high energy surfaces. In some cases, the circuit spacer layer 302D is formed by alternating materials of varying properties. For example, the circuit spacer layer 302D may be formed by alternating a first layer of the aforementioned adhesive material with a next layer of thermoplastic (e.g., PET) and a second, final layer of the adhesive material. In such cases, the first and second layers of adhesive material may each have a thickness of approximately 0.06 mm, but the thickness of the first and/or second layers for the adhesive material may vary. In the illustrated example, the thickness of the circuit spacer layer 302D, as a whole, is approximately 0.225 mm, although this thickness may also vary. As shown with brief reference to FIG. 3D, the circuit spacer layer 302D of various examples may be formed having one or more openings 305 shaped to accommodate a segment display and a dome of a membrane switch formed therein.

Continuing on with reference once again to FIG. 3A, the illustrated back adhesive layer 302E generally serves to securely bond the assembly casing 300 to a mounting surface (not shown). Ideally, the material chosen to form the back adhesive layer 302E exhibits properties such as lightness and shatter-resistance that make it a suitable alternative to glass. In some cases, the back adhesive layer 302E is formed by alternating materials of varying properties such as an adhesive material and a stronger acrylic material. For example, the back adhesive layer 302E may be formed by alternating a first layer of DT6125 and a second layer of PMMA. Though, it will be understood by those of skill in the art that other suitable materials—such as one or more other adhesive materials or one or more other acrylics—are contemplated herein. In one such embodiment wherein the back adhesive layer 302E is formed according to this method, the back adhesive layer 302E may comprise a first DT6125 layer of thickness approximately 0.255 mm and a second PMMA layer of thickness approximately 1.5 mm. Though, alternative thicknesses of the respective layers of a back adhesive layer 302E are contemplated while maintaining an overall thickness of approximately 1.725 mm. Finally, and with brief reference to FIG. 3E, the back adhesive layer 302E of various examples may be formed having one or more openings 306 shaped to accommodate a segment display and a dome of a membrane switch (and/or other components) formed therein.

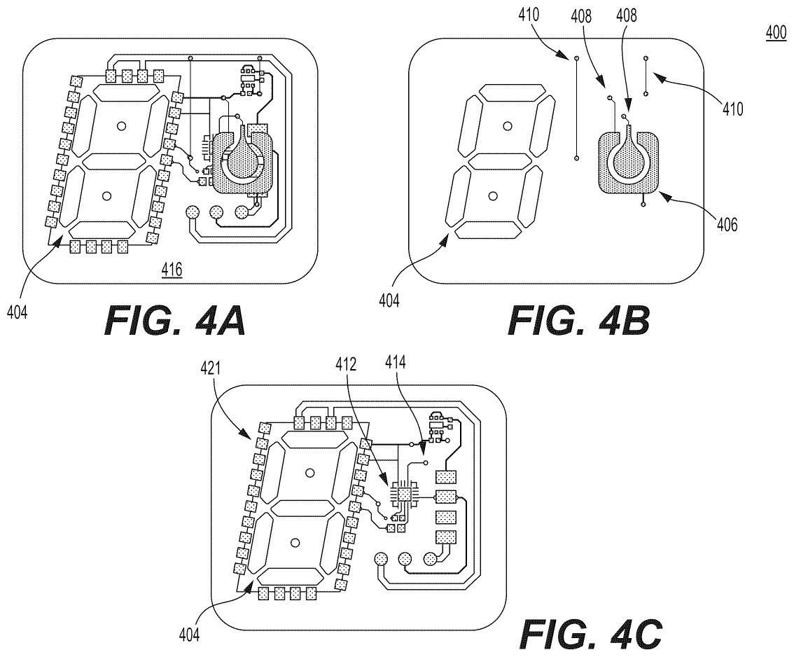

Turning now to FIG. 4A-4C, illustrated therein are various plan views of an exemplary embodiment of a PCB 400, which comprises the substrate for a membrane switch. FIGS. 4B-4C illustrate components of the PCB 400 that are otherwise not visible in FIG. 4A. The selected material of which PCB 400 is formed is ideally a durable and water-resistant insulator such as glass-reinforced epoxy laminate (e.g., FR4). Techniques known in the art such as plating or etching away copper (or other conductive material), or printing a conductive material can be used for forming electrically conductive traces on a substrate 416 in a desired shape and configuration. The PCB 400 may be manufactured having a copper thickness of approximately 1 oz. (e.g., 1.37 mils or 0.0348 mm).

Ideally, the PCB 400 of the illustrated example is formed having a thickness of approximately 1.6 mm and comprising two copper layers. A first copper layer, illustrated in FIG. 4B, comprises a conductive pattern 406 having a discontinuity formed therein so that conductive pattern 406 generally maintains an open circuit. When a force is applied in a direction generally perpendicular to the surface of the conductive pattern 406 to bring a dome of a membrane switch in contact with the conductive pattern 406, the conductive pattern 406 changes from a non-conducting state to a conducting state. Conductive pattern 406 is applied in direct contact with conductive traces 408. Thus, in the conducting state, an electrical current can readily be conveyed to conductive traces 408 through the conductive pattern 406. In the illustrated view, PCB 400 also comprises conductive traces 410. While the foregoing description refers to the illustrated PCB 400 as including two copper layers, it will be understood that the instant disclosure is not so limited. For instance, this disclosure contemplates other configurations including PCBs having any of four copper layers, six copper layers or more. Still in other examples, the PCB 400 may comprise an etched copper flexible circuit (FPC). In such examples, the PCB 400 may thus comprise a thin copper sheet laminated onto a flexible substrate (such as polyimide). Accordingly, fabrication may include etching away specific patterns of copper to form conductive traces and thereby rendering a flexible circuit suitable for use in wearable electronics, medical devices, smartphones, tablets, automotive parts, etc.

Continuing, with reference to FIG. 4C, the PCB 400 may further comprise a second copper layer. Specifically, the second copper layer has disposed thereon a microcontroller 412 and various conductive leads and traces for interfacing with components such as LED array 404. The microcontroller 412 is configured in electrical communication with conductive pattern 406 via conductive traces 408 and conductive lead 414. Moreover, two of conductive pads 421 are in electrical contact with the microcontroller 412 via the conductive leads 422. In this way, activation of the membrane switch (and therefore activation of the conductive pattern 406 to a conducting state) enables electrical communication between the microcontroller 412 and the LED array 404. The microcontroller 412 is thus configured with sufficient random access memory (RAM) to accommodate the LED array 404. In one example embodiment, the microcontroller 412 is configured with at least two gigabytes of RAM, and is therefore capable of controlling an LED array comprising at least twenty-one addressable LEDs.

Terminals 418 are disposed on one end of the PCB 400, and two of the terminals 418 are coupled to conductive traces 420 and 422. As such, the terminals 418 may be in electrical communication with the microcontroller 412 and the voltage regulator 424. Voltage regulator 425 may generally serve to prevent potential damage to the LED array 404 that could be caused by voltage fluctuations. The terminals 418 are spaced apart and configured to couple to a terminal (such as terminal 208 shown and described with reference to FIG. 2). Alternatively, the terminals 418 can be configured to connect to external lead wires (not shown), for example, by using a solder connection.

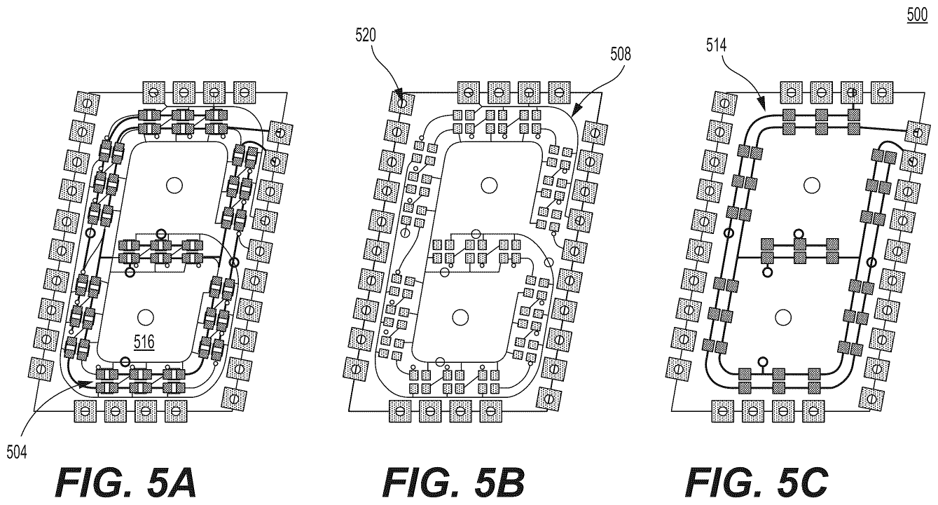

FIGS. 5A-5C illustrates a plan view an exemplary embodiment of a PCB 500, which serves as a substrate for an LED array 504. FIGS. 5B-5C are plan views of various components of the PCB 500 that are not otherwise easily seen in FIG. 5A. The material selected as the substrate 516 on which PCB 500 is formed may be similar to or the same as that from which the PCB 400 described above with reference to FIGS. 4A-4C is formed. Also similarly to the PCB 400, the exemplary PCB 500 may comprise two copper layers each with a copper thickness of approximately 1 oz. However, the PCB 500 is ideally thinner than the above described PCB 400. In one example, the PCB 500 has a thickness of approximately 1.0 mm (within a tolerance of +/−0.5 mm).

FIG. 5B illustrates a first copper layer of the PCB 500, on which various electrical connections are formed. As illustrated, an array of vias 520 (also referred to herein as through-holes) are formed in the first copper layer, around the periphery of an LED array 504. This array of vias 520 generally serves to electrically couple the LED array substrate of embodiments to various components of a membrane switch substrate. Generally, one set of the illustrated vias 520 allows an electrical signal to pass from the LED array 504 to an input voltage source. Further, another set of the illustrated vias 520 allows passage of an electrical signal to a voltage regulator and microcontroller, such as the microcontroller 412 and the voltage regulator 424 described above with regard to FIGS. 4A-4C. Conductive traces 508 are also formed on the first copper layer to electrically couple the LEDs of the LED array 504 to one another. Briefly, with reference to FIG. 5C, shown therein is a second copper layer of the PCB 500, on which are formed various electrical leads 514 for electrically coupling the LED array 504 to the various components of the membrane switch substrate.

In an exemplary embodiment, the LED array 504 comprises addressable LEDs and thus enhanced control of the LED array 504 is afforded. Ideally, the LED array 504 comprises red, green, and blue (RGB) addressable LEDs and/or red, green, blue, and white (RGBW) addressable LEDs. Accordingly, the digital display assembly of an exemplary embodiment is configured to simulate a myriad of colors that cannot be achieved with conventional seven segment displays. For example, a controller (such as the microcontroller described above with reference to FIGS. 4A-4C) may be used to control one or more individual LEDs of LED array 504-i.e., by changing an intensity of one or more colors emitted by the individual LEDs. Alternatively, the addressable LEDs of the LED array 504 may comprise built-in control integrated circuits. Moreover, the addressable LEDs of the LED array 504 may take any suitable form factor such as PTH (i.e., “through-hole”) or SMT (i.e., “surface mount”).

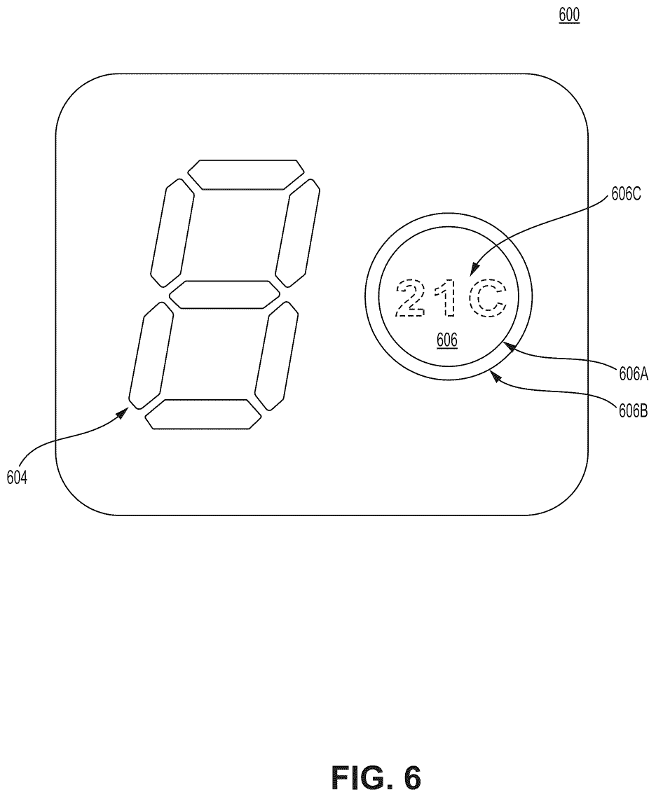

FIG. 6 is a plan view of an exemplary protective sheet 600, wherein the protective sheet includes graphics indicating the location of a membrane switch in accordance with the present approach. In particular, the exemplary protective sheet 600 illustrates a configuration that is useful for data entry. The protective sheet 600 may be similar to the overlay layer 302A described above with reference to FIG. 3A. In the illustrated example, the protective sheet 600 is made of relatively thin plastic, having a thickness of approximately 0.18 mm. However, the protective sheet 600 can be fabricated from other appropriate materials such as plastic or glass. This material is translucent, ideally, with a solid-color background around the position of a membrane switch, such as position 606, that overlies a membrane switch associated with selecting the numbers 0 through 9 illuminated by LED array 604. The location of the membrane switch is thus indicated in the illustrated example by the concentric circles 606A and 606B that encompass the numbers/text 606C used to indicate the functions of the membrane switch.

As an option, graphics can be applied as a separate sheet (not specifically shown) or the graphics can be printed directly onto or incorporated integrally in the protective sheet 600. Because the described membrane switch responds to pressure, the protective sheet 600 does not necessarily have to be flexible, so long as it is able to transmit the force applied to a position on the overlay layer that overlies the membrane switch.

The preceding description has been provided to enable others skilled in the art to best utilize various aspects of the example embodiments disclosed herein. This example description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and/or indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A digital display assembly, comprising:
an overlay layer configured to convey alphanumeric information and receive user input, the overlay layer including:
an array of openings in a top surface of the overlay layer, an individual opening of the array of openings configured to receive an individual light emitting diode (LED) of a segment display, and
a raised area configured to provide tactile feedback via a tactile membrane switch;
a first printed circuit board (PCB) disposed beneath the overlay layer and comprising a substrate on which the tactile membrane switch is formed, the tactile membrane switch being in electrical communication with the segment display and a microcontroller disposed on the first PCB;
a second PCB disposed beneath the overlay layer and comprising a substrate on which the segment display is disposed, the segment display being in electrical communication with the tactile membrane switch and the microcontroller; and
a back adhesive layer disposed beneath the first PCB and the second PCB.

2. The digital display assembly of claim 1, wherein the overlay layer comprises a protective sheet of plastic that graphically indicates a location of the tactile membrane switch.

3. The digital display assembly of claim 1, wherein a thickness of the digital display assembly is between approximately 3.7 mm and approximately 3.9 mm.

4. The digital display assembly of claim 1, wherein the tactile membrane switch comprises a dome structure disposed to compress in response to a pressure applied to the raised area.

5. The digital display assembly of claim 4, wherein the dome structure comprises one of metal or plastic having conductive ink disposed on an underside of the dome structure.

6. The digital display assembly of claim 1, wherein the segment display is one of a seven segment display, a nine segment display, a twelve segment display, a fourteen segment display, or a sixteen segment display.

7. The digital display assembly of claim 1, wherein the microcontroller is programmed to cause, in response to receiving first tactile input via the tactile membrane switch, the seven segment display to perform a first function, the first function being one of a timer, a clock, or a stopwatch.

8. The digital display assembly of claim 7, wherein the microcontroller is programmed to cause, in response to receiving second tactile input via the tactile membrane switch, the seven segment display to perform a second function that is different than the first function.

9. A digital display assembly, comprising:
an overlay layer configured to convey alphanumeric information and receive user input, the overlay layer including:
an array of openings in a top surface of the overlay layer, an individual opening of the array of openings configured to receive a dot matrix display, and
a raised area configured to provide tactile feedback via a tactile membrane switch;
a first printed circuit board (PCB) disposed beneath the overlay layer and comprising a substrate on which the tactile membrane switch is formed, the tactile membrane switch being in electrical communication with the seven segment display and a microcontroller disposed on the first PCB;
a second PCB disposed beneath the overlay layer and comprising a substrate on which the seven segment display is disposed, the seven segment display being in electrical communication with the tactile membrane switch and the microcontroller; and
a back adhesive layer disposed beneath the first PCB and the second PCB.

10. The digital display assembly of claim 9, wherein the overlay layer comprises a protective sheet of plastic that graphically indicates a location of the tactile membrane switch.

11. The digital display assembly of claim 9, wherein a thickness of the digital display assembly is between approximately 3.7 mm and approximately 3.9 mm.

12. The digital display assembly of claim 9, wherein the tactile membrane switch comprises a dome structure disposed to compress in response to a pressure applied to the raised area.

13. The digital display assembly of claim 12, wherein the dome structure comprises one of metal or plastic having conductive ink disposed on an underside of the dome structure.

14. The digital display assembly of claim 9, wherein the dot matrix display comprises one or more addressable LEDs.

15. A digital display assembly, comprising:
an overlay layer configured to convey alphanumeric information and receive user input, the overlay layer including:
an array of openings in a top surface of the overlay layer, an individual opening of the array of openings configured to receive an individual light emitting diode (LED) of a digital display, and
a raised area configured to provide tactile feedback via a tactile membrane switch;
a first printed circuit board (PCB) disposed beneath the overlay layer and comprising a substrate on which the tactile membrane switch is formed, the tactile membrane switch being in electrical communication with the seven segment display and a microcontroller disposed on the first PCB;
a second PCB disposed beneath the overlay layer and comprising a substrate on which the seven segment display is disposed, the seven segment display being in electrical communication with the tactile membrane switch and the microcontroller; and
a back adhesive layer disposed beneath the first PCB and the second PCB.

16. The digital display assembly of claim 15, wherein the overlay layer comprises a protective sheet of plastic that graphically indicates a location of the tactile membrane switch.

17. The digital display assembly of claim 15, wherein a thickness of the digital display assembly is between approximately 3.7 mm and approximately 3.9 mm.

18. The digital display assembly of claim 15, wherein the tactile membrane switch comprises a dome structure disposed to compress in response to a pressure applied to the raised area.

19. The digital display assembly of claim 15, wherein the microcontroller is programmed to:
cause, in response to receiving first tactile input via the tactile membrane switch, the digital display to perform a first function, the first function being one of a timer, a clock, or a stopwatch; and
cause, in response to receiving second tactile input via the tactile membrane switch, the digital display to perform a second function that is different than the first function.

20. The digital display assembly of claim 14, wherein the digital display comprises one or more addressable LEDs.
